(19) United States
(12) Patent Application Publication
(10) Pub. No.: US 2017/0149206 A1
(43) Pub. Date: May 25, 2017

(54) CONTROL METHOD OF SPEEDING UP LIGHT EMISSION OF LASER DIODES

(71) Applicant: INDUSTRIAL TECHNOLOGY RESEARCH INSTITUTE, HSINCHU (TW)

(72) Inventors: FU-ZEN CHEN, TAIPEI CITY (TW); FU-SHUN HO, TAINAN CITY (TW); CHUN-CHIEH YANG, KAOHSIUNG CITY (TW); YU-CHENG SONG, TAINAN CITY (TW); YAO-WUN JHANG, CHIAYI CITY (TW)

(21) Appl. No.: 14/978,659

(22) Filed: Dec. 22, 2015

(30) Foreign Application Priority Data
Nov. 25, 2015 (TW) 104139267

(51) Int. Cl. H01S 5/042; H01S 5/022

(52) U.S. Cl. CPC H01S 5/042; H01S 5/0425; H01S 5/02248

(57) ABSTRACT

A control method of speeding up light emission of a laser diode includes the following steps. First step is to boost the supply voltage from a first voltage potential to a second voltage potential before an emission period. At the beginning of the emission period, a current path conducts through the laser diode and a current source. One terminal of the laser diode is coupled to the current source, and the other terminal of the laser diode connects the supply voltage. When the current path is being conducted, the current source is in the transient state and provides a transient driving current; and the voltage difference between the two terminals of the laser diode is generated in response to the second voltage potential and is related to the transient driving current. When the transient driving current is larger than a threshold, the laser diode emits light.

### CROSS-REFERENCE TO RELATED APPLICATIONS

This non-provisional application claims priority under 35 U.S.C. §119(a) on Patent Application No(s). 104139267 filed in Taiwan, R.O.C. on Nov. 25, 2015, the entire contents of which are hereby incorporated by reference.

### TECHNICAL FIELD

The disclosure relates to a control method of speeding up light emission of light amplification by simulated emission of radiation (Laser) diodes.

### BACKGROUND

A laser is a device that emits light through a process of optical amplification based on the stimulated emission of electromagnetic radiation. All photons outputted by a laser have the same phase, direction and amplitude so laser light has a high intensity, directionality, a monochromatism and coherences. Due to the properties of laser light, industrial lasers has been applied to applications of precision machining in various industries. A laser can provide a focused high energy thermal source for applications of various fields, such as high speed welding, cutting, marking, engraving, coloring, surface heat treatment or measurement.

Presently, a more common practice is that one or more laser diodes cooperate with a driving device to produce laser light. A user can use the driving device to control the laser diode to emit light or not to process workpieces according to the states of the workpieces. However, existed driving devices generally cannot rapidly turn on laser diodes to produce laser light, resulting in a lower processing quality usually caused by the delay of light emission of laser diodes during workpiece machining.

### SUMMARY

According to one or more embodiments, the disclosure provides a control method of speeding up light emission of laser diodes. The control method includes the following steps. Boost a supply voltage from a first voltage potential to a second voltage potential before an emission period starts. At the beginning of the emission period, conduct a current path comprising the laser diode and a current source. One terminal of the laser diode is coupled to the current source, and the other terminal of the laser diode connects to the supply voltage. When the current path is being conducted, the current source is in the transient state and provides a transient driving current; and the voltage difference between the two terminals of the laser diode is generated in response to the second voltage potential and is related to the transient driving current. When the transient driving current is larger than a threshold, the laser diode emits light.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a block diagram of a laser output device in an embodiment;

FIG. 2 is a flow chart of the control method in speeding up the light emission of laser diodes in an embodiment;

FIG. 3A is a time sequence diagram of each node voltage in the control method in an embodiment; and

FIG. 3B is a time sequence diagram of a driving current in the control method in an embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

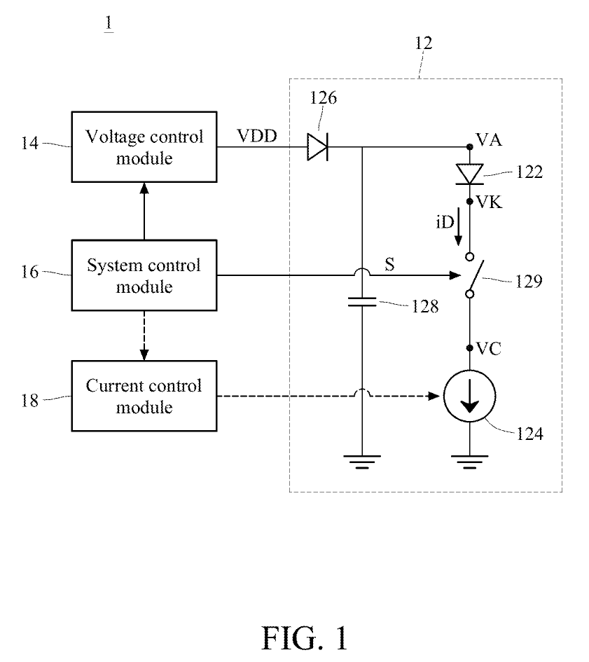

Please refer to FIG. 1. FIG. 1 is block diagram of a laser output device 1 in an embodiment. The laser output device 1 includes a laser diode driving module 12, a system control module 16, a voltage control module 14 and a current control module 18. The laser diode driving module 12 is electrically connected to the system control module 16, the voltage control module 14 and the current control module 18, and the system control module 16 is electrically connected to the voltage control module 14 and the current control module 18. The laser diode driving module 12 includes a laser diode 122, a current source 124, a diode 126, a capacitor 128 and a switch unit 129. In an embodiment, the switch unit 129, the laser diode 122 and the current source 124 are connected in series, and a series of the switch unit 129, the laser diode 122 and the current source 124 is connected to the capacitor 128 in parallel. A terminal of the diode 126 is electrically connected to the capacitor 128 and the laser diode 122.

Multiple voltage parameters and current parameters are presented in FIG. 1. A voltage potential VA represents a voltage on one terminal of the laser diode 122, and a voltage potential VK represents a voltage on the other terminal of the laser diode 122. A terminal of the current source 124 is coupled to a ground end. A voltage potential VC represents a voltage on the other terminal of the current source 124. A terminal of the diode 126 connects to a supply voltage VDD. In another embodiment, the laser diode driving module 12 does not have the diode 126 and uses the inner property of the voltage control module 14 to maintain voltages, and the laser diode 122 and the capacitor 128 directly receives the supply voltage VDD.

The voltage control module 14 selectively provides the supply voltage VDD and even selectively boosts the supply voltage VDD from a first voltage potential V1 to a second voltage potential V2. The first voltage potential V1 and the second voltage potential V2 are exemplary but are not used to limit the range of the supply voltage VDD and the amount of output potentials. The current control module 18 controls the current source 124 to selectively provide a driving current iD. The system control module 16 commands the voltage control module 14 and the current control module 18 according to a power setting signal and according to the power setting signal, selectively outputs a control signal S for turning on the switch unit 129. In other words, the system control module 16, according to an output power value indicated by the power setting signal, commands the voltage control module 14 and the current control module 18 to correspondingly output the supply voltage VDD and the driving current iD. In an embodiment, when the control signal S is at a high voltage potential, the switch unit 129 is turned on. Other embodiments may be contemplated in which the switch unit 129 is turned on according to the control signal S at another voltage potential.

The current source 124 and the switch unit 129 are carried out by, for example, but not limited to, at least one bipolar junction transistor (BJT) or at least one metal-oxide-semiconductor field-effect transistor (MOSFET).

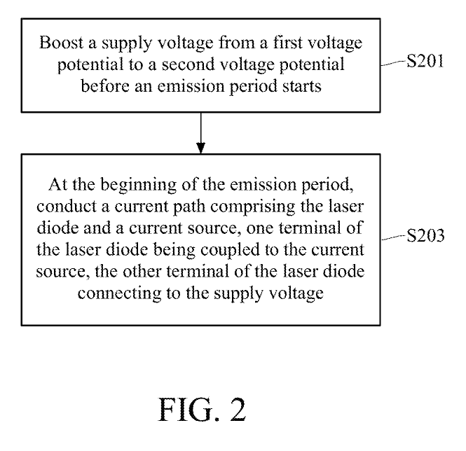

Also, the disclosure provides a control method of speeding up the light emission of laser diodes, as described in FIG. 2. FIG. 2 is a flow chart of a control method in speeding up the light emission of laser diodes in an embodiment. The control method includes the following steps. In step S201, a supply voltage is boosted from a first voltage potential to a second voltage potential before an emission period starts. In step S203, at the beginning of the emission period, the conducting of a current path starts, and meanwhile, the supply voltage drops to the first voltage potential. On the current path, there are a laser diode and a current source. One terminal of the laser diode is coupled to the current source, and the other terminal of the laser diode connects to the supply voltage. When the current path is being conducted, the current source is in the transient state and provides a transient driving current; and the voltage difference between the two terminals of the laser diode is generated in response to the second voltage potential and is related to the transient driving current. When the transient driving current is larger than a threshold, the laser diode emits light.

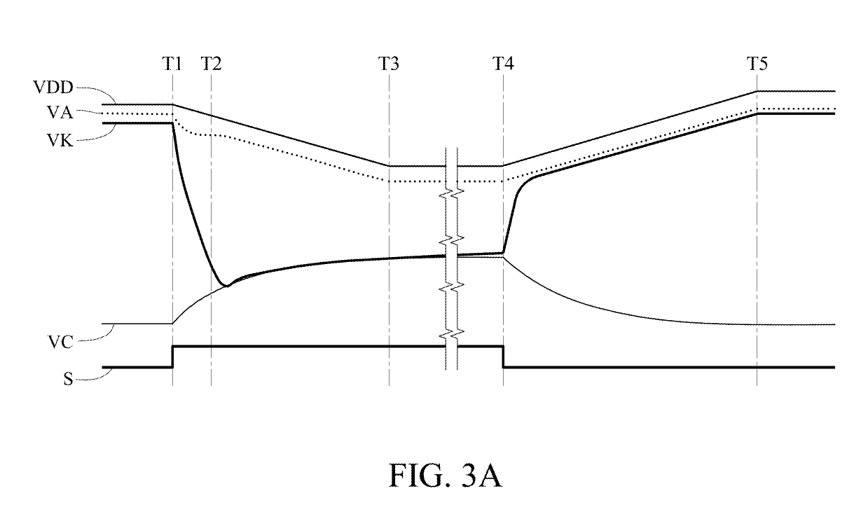

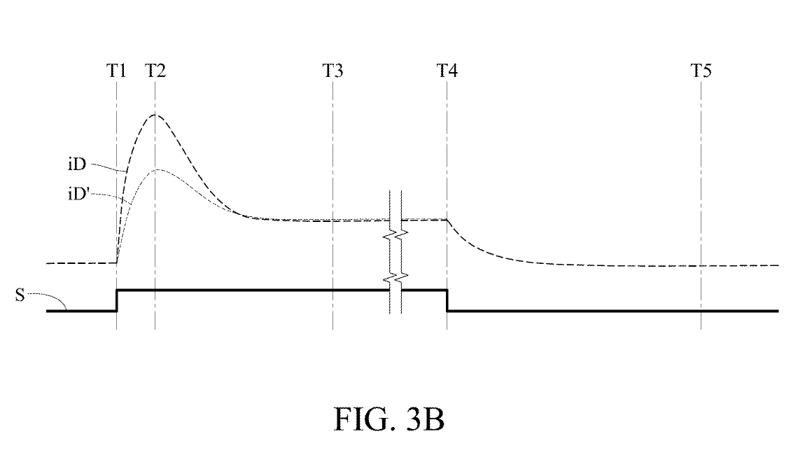

Please refer to FIGS. 3A and 3B to illustrate the above control method. FIG. 3A is a time sequence diagram of each node voltage in the control method in an embodiment, and FIG. 3B is a time sequence diagram of a driving current in the control method in an embodiment. As described in FIGS. 3A and 3B, a period between the time point T1 and the time point T4 is defined as an emission period. As described in FIG. 2˜FIG. 3B, the supply voltage VDD is boosted to a second voltage potential V2 by the time point T1. Herein, the voltage potential VA and the voltage potential VK are pulled to about the second voltage potential V2 in response. Because the control signal S herein is at a low voltage potential, the switch unit 129 is not turned on, the voltage potential VC is a low voltage potential, and the driving current iD is relatively small.

At the time point T1, the control signal S is modulated to a high voltage potential so the switch unit 129 is turning on. Also, the laser diode 122, the switch unit 129 and the current source 124 constitute a current path between an input node of the supply voltage VDD and a ground end, and the laser diode driving module 12 is in a transient state. Herein, the laser diode 122 is conducted but has not emitted light, the voltage potential VK decreases and gradually approaches the voltage potential VC, and the voltage potential VC increases and gradually approaches the voltage potential VK. Later than the time point Ti, the difference between the voltage potential VA and the voltage potential VK gradually increases; therefore, the driving current iD at the transient state also increases and achieves its peak value at around the time point T2. In this embodiment, the driving current iD at around the time point T2 becomes larger than the threshold current of the laser diode 122. The laser diode 122 starts emitting light at around the time point T2. In practice, the time point which the laser diode 122 starts emitting light is based on the physical properties of the laser diode 122 and is not limited by the above embodiment.

In an embodiment, after the time point T1 at which the switch unit 129 is turned on, boosting the supply voltage VDD to the second voltage potential V2 is stopped. Therefore, the supply voltage VDD gradually decreases after the time point T1, as shown in FIG. 3A. Accordingly, the voltage potential VA also decreases in response to the supply voltage VDD. The dropping speed of the supply voltage VDD and the dropping speed of the voltage potential VA are related to the capacitance of the capacitor 128, that is, related to the quantity of electric charges stored in the capacitor 128 before the time point T1 and the discharging speed and charging speed of the capacitor 128. In another embodiment, while the switch unit 129 is being turned on, boosting the supply voltage VDD to the second voltage potential V2 is stopped. In yet another embodiment, when the laser output device 1 has a structure as shown in FIG. 1, boosting the supply voltage VDD to the second voltage potential V2 is stopped before the switch unit 129 is turned on. Specifically, in this embodiment, before the switch unit 129 is turned on, the supply voltage VDD has increased to the second voltage potential V2 and boosting the supply voltage VDD also has been stopped. After boosting the supply voltage VDD is stopped, the supply voltage VDD gradually drops to the first voltage potential V1, and since the two terminals of the diode 126 are connected to the voltage control module 14 and the laser diode 122 respectively, the voltage potential VA is substantially latched at the second voltage potential V2. Therefore, the operation and performance of this embodiment may be similar to those of the previous embodiment. The above description is exemplified, and the disclosure will not be restricted to the above description.

After the time point T3, the laser diode driving module 12 gradually becomes stable so the supply voltage VDD is close to the first voltage potential V1 and is a constant value. The voltage potential VA is substantially a constant value close to the first voltage potential V1. Moreover, the variations of the voltage potentials VK and VC and the driving current iD gradually become substantially smooth. In the drawing, the transient peak of the driving current iD is larger than the steady-state potential of the driving current iD so that the laser diode 122 is rapidly turned on and emits light at the transient state.

At the time point T4, the control signal S is modulated to a low voltage potential so the switch unit 129 is turned off. Herein, the supply voltage VDD boosts to the second voltage potential V2 again. In practice, the increasing speed of the supply voltage VDD is related to the capacitance of the capacitor 128. Because the switch unit 129 is turned off, the voltage potentials VA and VK increase in response to the increase of the supply voltage VDD. On the other hand, the driving current iD and the voltage potential VC gradually drop to a constant value since the switch unit 129 is turned off. At the time point T5, the laser diode driving module 12 gradually becomes stable, and each voltage parameter and each current parameter also gradually become stable. Once the control signal S is pulled up to a high voltage potential again, the above process will proceed again.

FIG. 3B also shows the variation of the driving current iD′ of the laser diode 122 that is driven by a conventional way. As shown in FIG. 3B, when the control method is used to drive the laser diode 122, the driving current iD in the transient state is obviously larger than the driving current iD′. In other words, the driving current iD generated in the disclosure achieves the threshold current of the laser diode 122 faster so that the laser diode 122 more rapidly emits light. Because the laser output device 1 has no need to adjust its power value in the steady state, the output power value of the laser output device 1 in the steady state is not sacrificed. In addition, the disclosure only needs to use such voltage modulation control logic rather than using extra components, and thus, is saved from costs of extra equipment. On the whole, the transient state only needs an extremely short time, so the disclosure may not increase the power consumption of the entire circuit.

In view of the above control method of speeding up the light emission of laser diodes in the disclosure, the transient driving current of the laser diode increases in response to the boosting the supply voltage so the laser diode can rapidly emit light after being turned on by the transient driving current, which is higher than a conventional driving current. Also, the laser diode stably emits light in response to the steady-sate current after the circuit becomes stable. Therefore, the laser diode synchronously reacts to a user's command or a controller's control as far as it can. While the controller gives a command, the laser diode may rapidly emit light. Smaller delay of light emission can enhance the processing quality provided by the laser diode so the laser diode can be applied to a complicated precision machining field.

1. A control method of speeding up light emission of laser diodes, comprising:
boosting a supply voltage from a first voltage potential to a second voltage potential before an emission period starts; and
at the beginning of the emission period, conducting a current path comprising the laser diode and a current source, one terminal of the laser diode being coupled to the current source, another terminal of the laser diode receiving the supply voltage;
wherein when the current path is being conducted, the current source is in a transient state and outputs a transient driving current and a voltage difference between the two terminals of the laser diode is a transient voltage difference that is generated in response to the second voltage potential and is related to the transient driving current; and
when the transient driving current is larger than a threshold, the laser diode emits light;
wherein after the current path is conducted, the supply voltage is not boosted in order to modulate the supply voltage from the second voltage potential to the first voltage potential.

2. (canceled)

3. The control method according to claim 1, wherein a series of the laser diode and the current source is connected to a capacitor in parallel, and after boosting the supply voltage is stopped, dropping speed of the supply voltage is related to a capacitance of the capacitor.

4. (canceled)

5. (canceled)

6. The control method according to claim 1, wherein the laser diode is coupled to a diode, and the laser diode is coupled to the supply voltage through the diode.

7. The control method according to claim 6, further comprising:
stopping boosting the supply voltage in order to modulate the supply voltage from the second voltage potential to the first voltage potential after the supply voltage increases to the second voltage potential and before the current path is conducted.

8. The control method according to claim 7, wherein a series of the laser diode and the current source is connected to a capacitor in parallel, and after boosting the supply voltage is stopped, dropping speed of the supply voltage is related to a capacitance of the capacitor.

9. (canceled)

10. (canceled)

11. The control method according to claim 6, further comprising:
stopping boosting the supply voltage in order to modulate the supply voltage from the second voltage potential to the first voltage potential while the current path is being conducted.

12. The control method according to claim 11, wherein a series of the laser diode and the current source is connected to a capacitor in parallel, and after boosting the supply voltage is stopped, dropping speed of the supply voltage is related to a capacitance of the capacitor.

13. The control method according to claim 1, wherein a switch unit is coupled to the laser diode and the current source, and conducting the current path comprises turning on the switch unit to conduct the current path.

14. The control method according to claim 1, wherein after the current source is in a steady state, the current source outputs a steady-state driving current, and a maximum potential of the transient driving current is larger than a maximum potential of the steady-state driving current.

15. A control method of speeding up light emission of laser diodes, comprising:
boosting a supply voltage from a first voltage potential to a second voltage potential before an emission period starts; and
at the beginning of the emission period, conducting a current path comprising the laser diode and a current source, one terminal of the laser diode being coupled to the current source, another terminal of the laser diode receiving the supply voltage;
wherein when the current path is being conducted, the current source is in a transient state and outputs a transient driving current and a voltage difference between the two terminals of the laser diode is a transient voltage difference that is generated in response to the second voltage potential and is related to the transient driving current; and
when the transient driving current is larger than a threshold, the laser diode emits light;
wherein while the current path is being conducted, the supply voltage is not boosted in order to modulate the supply voltage from the second voltage potential to the first voltage potential.

16. The control method according to claim 15, wherein a series of the laser diode and the current source is connected to a capacitor in parallel, and after boosting the supply voltage is stopped, dropping speed of the supply voltage is related to a capacitance of the capacitor.

17. The control method according to claim 15, wherein the laser diode is coupled to a diode, and the laser diode is coupled to the supply voltage through the diode.

18. The control method according to claim 17, further comprising:
stopping boosting the supply voltage in order to modulate the supply voltage from the second voltage potential to the first voltage potential after the supply voltage increases to the second voltage potential and before the current path is conducted.

19. The control method according to claim 18, wherein a series of the laser diode and the current source is connected to a capacitor in parallel, and after boosting the supply voltage is stopped, dropping speed of the supply voltage is related to a capacitance of the capacitor.

20. The control method according to claim 17, further comprising:
stopping boosting the supply voltage in order to modulate the supply voltage from the second voltage potential to the first voltage potential after the current path is being conducted.

21. The control method according to claim 20, wherein a series of the laser diode and the current source is connected to a capacitor in parallel, and after boosting the supply voltage is stopped, dropping speed of the supply voltage is related to a capacitance of the capacitor.

22. The control method according to claim 15, wherein a switch unit is coupled to the laser diode and the current source, and conducting the current path comprises turning on the switch unit to conduct the current path.

23. The control method according to claim 15, wherein after the current source is in a steady state, the current source outputs a steady-state driving current, and a maximum potential of the transient driving current is larger than a maximum potential of the steady-state driving current.
